(19) United States
(12) Patent Application Publication
(10) Pub. No.: US 2016/0358762 A1
(43) Pub. Date: Dec. 8, 2016

(54) SEMICONDUCTOR MANUFACTURING SYSTEM AND SEMICONDUCTOR MANUFACTURING METHOD

(71) Applicant: Kabushiki Kaisha Toshiba, Minato-ku (JP)

(72) Inventors: Takayuki BEPPU, Yokkaichi (JP); Kazuaki NAKAJIMA, Yokkaichi (JP); Seiichi OMOTO, Yokkaichi (JP)

(73) Assignee: Kabushiki Kaisha Toshiba, Minato-ku (JP)

(21) Appl. No.: 14/836,080

(22) Filed: Aug. 26, 2015

Related U.S. Application Data
(60) Provisional application No. 62/170,333, filed on Jun. 3, 2015.

(51) Int. Cl. H01J 37/32; H01L 21/285; C23C 16/455; C23C 16/08; C23C 16/18

(52) U.S. Cl. CPC H01J 37/32889; C23C 16/08; C23C 16/18; C23C 16/45561; H01L 21/28556; H01J 2237/334

(57) ABSTRACT

In one embodiment, a semiconductor manufacturing system includes a gas supply module configured to supply an etching gas. The system further includes a chamber configured to house a substrate. The system further includes a metal member housing provided outside the chamber and configured to house a metal member, the metal member housing being configured to introduce the etching gas and to discharge a metal-containing gas that contains a metal etched from the metal member by the etching gas. Furthermore, the chamber is configured to introduce the metal-containing gas discharged from the metal member housing and to form a metal film on the substrate by the metal-containing gas.

### CROSS REFERENCE TO RELATED APPLICATION

This application is based upon and claims the benefit of priority from the prior U.S. Provisional Patent Application No. 62/170,333 filed on Jun. 3, 2015, the entire contents of which are incorporated herein by reference.

### FIELD

Embodiments described herein relate to a semiconductor manufacturing system and a semiconductor manufacturing method.

### BACKGROUND

When a semiconductor device is manufactured, various metal films are formed on a substrate. For example, such metal films are formed by chemical vapor deposition (CVD). However, when a new metal is to be adopted to the semiconductor device to form a new metal film on the substrate, there are problems of time and costs for preparing means to house a material of the metal film and means to supply a source gas of the metal film to a CVD chamber. A similar problem may also occur when the metal film is formed by a method other than the CVD.

### BRIEF DESCRIPTION OF THE DRAWINGS

FIG. 1 is a schematic diagram illustrating a configuration of a semiconductor manufacturing system of a first embodiment;

FIGS. 2A and 2B are sectional views illustrating examples of a metal film of the first embodiment;

FIGS. 3A to 3C are sectional views illustrating examples of a first metal member of the first embodiment;

FIG. 4 is a schematic diagram illustrating a configuration of a semiconductor manufacturing system of a second embodiment;

FIG. 5 is a schematic diagram illustrating a configuration of a semiconductor manufacturing system of a third embodiment; and

FIG. 6 is a schematic diagram illustrating a configuration of a semiconductor manufacturing system of a fourth embodiment.

### DETAILED DESCRIPTION

Embodiments will now be explained with reference to the accompanying drawings.

In one embodiment, a semiconductor manufacturing system includes a gas supply module configured to supply an etching gas. The system further includes a chamber configured to house a substrate. The system further includes a metal member housing provided outside the chamber and configured to house a metal member, the metal member housing being configured to introduce the etching gas and to discharge a metal-containing gas that contains a metal etched from the metal member by the etching gas. Furthermore, the chamber is configured to introduce the metal-containing gas discharged from the metal member housing and to form a metal film on the substrate by the metal-containing gas.

### First Embodiment

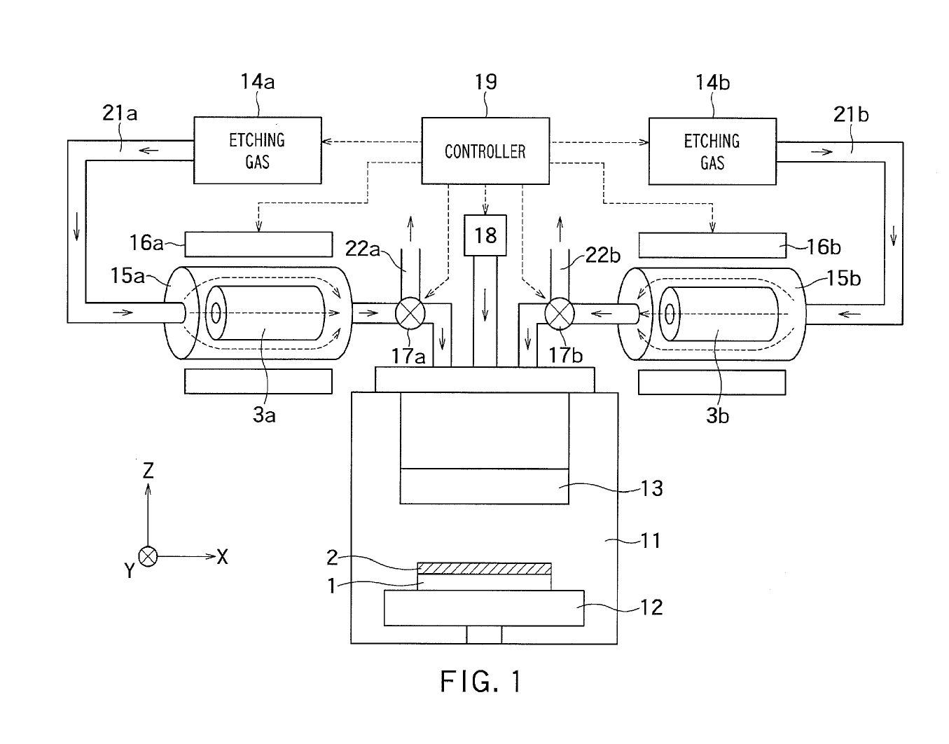

FIG. 1 is a schematic diagram illustrating a configuration of a semiconductor manufacturing system of a first embodiment.

The semiconductor manufacturing system in FIG. 1 includes a chamber 11, a stage 12, a shower head 13, first and second gas supply modules 14a and 14b, first and second vaporizers 15a and 15b, first and second heaters 16a and 16b, first and second exhaust valves 17a and 17b, a reducing gas supply module 18 and a controller 19. The first and second vaporizers 15a and 15b are examples of a metal member housing. The first and second heaters 16a and 16b are examples of a heating module. The first and second exhaust valves 17a and 17b are examples of a valve.

The chamber 11 is used to house a substrate (wafer) 1. The chamber 11 of the present embodiment is a CVD chamber that forms a metal film 2 on the substrate 1 by CVD. The stage 12 and the shower head 13 are provided inside the chamber 11. The stage 12 supports the substrate 1 in the chamber 11, and the shower head 13 supplies a gas into the chamber 11. Examples of the gas are a source gas for forming the metal film 2, and a reducing gas for reducing the source gas.

FIG. 1 illustrates X and Y directions that are parallel to a surface of the substrate 1 and are perpendicular to each other, and a Z direction that is perpendicular to the surface of the substrate 1. In this specification, a +Z direction is handled as an upper direction and a −Z direction is handled as a lower direction. For example, a positional relation between the substrate 1 and the shower head 13 is expressed as that the substrate 1 is arranged below the shower head 13. The −Z direction in the present embodiment may coincide with a gravity direction or may not coincide with the gravity direction.

The first gas supply module 14a supplies a first etching gas to a flow path 21a between the first gas supply module 14a and the chamber 11. The second gas supply module 14b supplies a second etching gas to a flow path 21b between the second gas supply module 14b and the chamber 11.

The first and second etching gases of the present embodiment contain a halogen. Molecules configuring these etching gases may be elemental molecules containing the halogen or may be compound molecules containing the halogen. Examples of these etching gases are a chlorine (Cl₂) gas and a fluorine (F₂) gas. The second etching gas may be the same gas as the first etching gas or may be a gas different from the first etching gas.

The first vaporizer 15a is provided on the flow path 21a outside the chamber 11, and houses a first metal member 3a. When the first etching gas is introduced from the flow path 21a into the first vaporizer 15a, the first metal member 3a is etched by the first etching gas. As a result, the first vaporizer 15a discharges a first metal-containing gas that contains a metal etched from the first metal member 3a to the flow path 21a.

For example, when the first metal member 3a is a titanium (Ti) member and the first etching gas is a chlorine gas, an example of the first metal-containing gas is a titanium chloride gas such as a TiCl₄ gas. The first metal-containing gas is used as the source gas of the metal film 2. The first metal member 3a of the present embodiment is configured as a cartridge type attachable to and detachable from the first vaporizer 15a.

The second vaporizer 15b is provided on the flow path 21b outside the chamber 11, and houses a second metal member 3b. When the second etching gas is introduced from the flow path 21b into the second vaporizer 15b, the second metal member 3b is etched by the second etching gas. As a result, the second vaporizer 15b discharges a second metal-containing gas that contains a metal etched from the second metal member 3b to the flow path 21b.

For example, when the second metal member 3b is a tantalum (Ta) member and the second etching gas is a chlorine gas, an example of the second metal-containing gas is a tantalum chloride gas such as a TaCl₅ gas. The second metal-containing gas is used as the source gas of the metal film 2. The second metal member 3b of the present embodiment is configured as the cartridge type attachable to and detachable from the second vaporizer 15b.

It is desirable that the first metal member 3a has a hole through which the first etching gas passes, as illustrated in FIG. 1. The reason is that a contact area of the first metal member 3a and the first etching gas becomes large, and the first metal member 3a is easily etched. The first metal member 3a of the present embodiment contains a group 4, 5 or 6 metal element that easily reacts with the halogen. Examples of such a metal element is titanium (Ti), zirconium (Zr), hafnium (Hf), vanadium (V), niobium (Nb), tantalum (Ta), chromium (Cr), molybdenum (Mo), tungsten (W) or the like. The first metal member 3a may contain only one kind of metal element or may contain two or more kinds of metal elements.

The above is similarly adopted to the second metal member 3b. A shape and a material of the second metal member 3b may be the same as the first metal member 3a or may be different from the first metal member 3a.

The first heater 16a heats the first metal member 3a in the first vaporizer 15a. As a result, etching of the first metal member 3a is accelerated. The second heater 16b heats the second metal member 3b in the second vaporizer 15b. As a result, etching of the second metal member 3b is accelerated.

The first heater 16a of the present embodiment can generate the first metal-containing gas by heating the first metal member 3a so that a temperature of the first metal member 3a becomes equal to or higher than a melting point of the molecules configuring the first metal-containing gas. For example when the first metal member 3a, the first etching gas and the first metal-containing gas are respectively a Ti member, a Cl₂ gas and a TiCl₄ gas, the Ti member is heated so that the temperature of the Ti member becomes equal to or higher than the melting point of the TiCl₄ gas. Also, the first heater 16a of the present embodiment can further accelerate generation of the first metal-containing gas by heating the first metal member 3a so that the temperature of the first metal member 3a becomes equal to or higher than a boiling point of the molecules configuring the first metal-containing gas. The above is similarly adopted to the second heater 16b.

The first exhaust valve 17a is provided on the flow path 21a between the first vaporizer 15a and the chamber 11. The first exhaust valve 17a is used to control supply of the first metal-containing gas from the first vaporizer 15a to the chamber 11. The first exhaust valve 17a of the present embodiment is provided at a contact point of the flow path 21a and a flow path 22a.

The second exhaust valve 17b is provided on the flow path 21b between the second vaporizer 15b and the chamber 11. The second exhaust valve 17b is used to control supply of the second metal-containing gas from the second vaporizer 15b to the chamber 11. The second exhaust valve 17b of the present embodiment is provided at a contact point of the flow path 21b and a flow path 22b.

The first exhaust valve 17a of the present embodiment can switch whether or not to supply the first metal-containing gas to the chamber 11. When the first exhaust valve 17a is switched to the side of the chamber 11, the first metal-containing gas is supplied through the flow path 21a to the chamber 11. On the other hand, when the first exhaust valve 17a is switched to the side of the flow path 22a, the first metal-containing gas is not supplied to the chamber 11, and is exhausted to the flow path 22a. For example, the flow path 22a is used to exhaust the first metal-containing gas without using it when a metal concentration in the first metal-containing gas is low immediately after activation of the semiconductor manufacturing system. The above is similarly adopted to the second exhaust valve 17b.

The reducing gas supply module 18 supplies, to the chamber 11, the reducing gas that reduces the first and second metal-containing gases. Examples of the reducing gas are an ammonia (NH₃) gas, a monosilane (SiH₄) gas and a disilane (Si₂H₆) gas. For example, when the first metal-containing gas is a TiCl₄ gas, TiCl₄ in the first metal-containing gas is reduced to Ti, so that a Ti film is formed as the metal film 2 on the substrate 1.

The controller 19 controls various operations of the semiconductor manufacturing device. The controller 19 controls, for example, the operation of the chamber 11, elevation/lowering and rotation of the stage 12, ON/OFF and a gas flow rate of the first and second gas supply modules 14a and 14b or the like. Also, the controller 19 controls, for example, ON/OFF and a heating amount of the first and second heaters 16a and 16b, changeover of the first and second exhaust valves 17a and 17b, ON/OFF and a gas flow rate of the reducing gas supply module 18 or the like.

The controller 19 of the present embodiment detects the temperature of the first metal member 3a by a temperature detector provided in the first vaporizer 15a or the first heater 16a, and controls the ON/OFF and the heating amount of the first heater 16a based on the temperature received from the temperature detector. The controller 19 can thereby control the temperature of the first metal member 3a to be equal to or higher than the melting point or the boiling point of the molecules configuring the first metal-containing gas. The temperature detector may directly measure the temperature of the first metal member 3a, or may estimate the temperature of the first metal member 3a from a measurement result of another temperature. The above is similarly adopted to the second metal member 3b.

Next, the chamber 11 in FIG. 1 will be described again.

The first metal-containing gas, the second metal-containing gas and the reducing gas are introduced from the shower head 13 into the chamber 11. The first metal-containing gas contains a metal element that configures the first metal member 3a (e.g., titanium). The second metal-containing gas contains a metal element that configures the second metal member 3b (e.g., tantalum).

When the first metal-containing gas is introduced into the chamber 11, the metal film 2 is formed on the substrate 1 by the metal element in the first metal-containing gas. In a case where the first metal-containing gas is the TiCl₄ gas, an example of the metal film 2 is a Ti film. In this case, in order to reduce TiCl₄ to Ti, the reducing gas is also introduced from the reducing gas supply module 18 into the chamber 11. In a case where it is not needed to cause reducing reaction in forming the metal film 2 on the substrate 1, the reducing gas may not be introduced from the reducing gas supply module 18 into the chamber 11.

When the second metal-containing gas is introduced into the chamber 11, the metal film 2 is formed on the substrate 1 by the metal element in the second metal-containing gas. In a case where the second metal-containing gas is the TaCl₅ gas, an example of the metal film 2 is a Ta film. In this case, in order to reduce TaCl₅ to Ta, the reducing gas is also introduced from the reducing gas supply module 18 into the chamber 11. In a case where it is not needed to cause the reducing reaction when forming the metal film 2 on the substrate 1, the reducing gas may not be introduced from the reducing gas supply module 18 into the chamber 11.

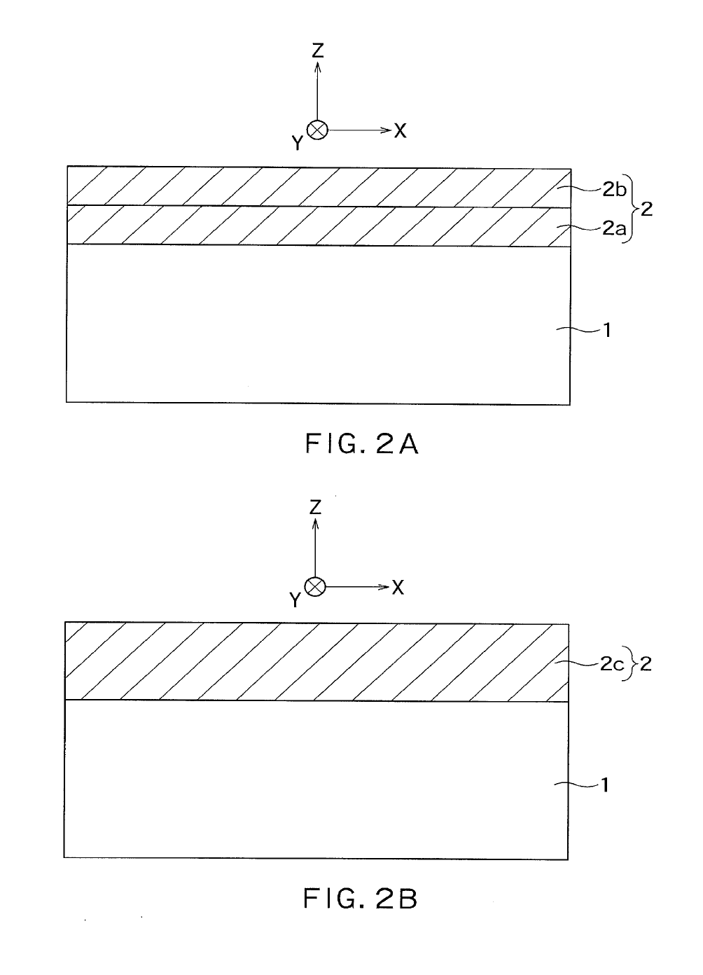

FIGS. 2A and 2B are sectional views illustrating examples of the metal film 2 of the first embodiment.

The metal film 2 in FIG. 2A includes a first metal film 2a formed on the substrate 1, and a second metal film 2b formed on the first metal film 2a. The metal film 2 in FIG. 2A can be formed, for example, by introducing the first metal-containing gas into the chamber 11 to form the first metal film 2a, and then introducing the second metal-containing gas into the chamber 11 to form the second metal film 2b.

The metal film 2 in FIG. 2B includes a metal film 2c that is an alloy. The metal film 2 in FIG. 2B can be formed, for example, by simultaneously introducing the first and second metal-containing gases into the chamber 11 to form the metal film 2c containing the metal element in the first metal-containing gas and the metal element in the second metal-containing gas.

The metal film 2c of the alloy may be formed using only the first metal member 3a (or only the second metal member 3b). In this case, the first metal member 3a is a metal member containing first and second metal elements, for example. The first metal member 3a may include a first elemental metal layer containing the first metal element and a second elemental metal layer containing the second metal element, or may include an alloy layer containing the first and second metal elements.

Also, each of the first and second metal films 2a and 2b may be an elemental metal film or an alloy film. The alloy film may be also formed using both of the first and second metal-containing gases, or may be formed using only one of the first and second metal-containing gases.

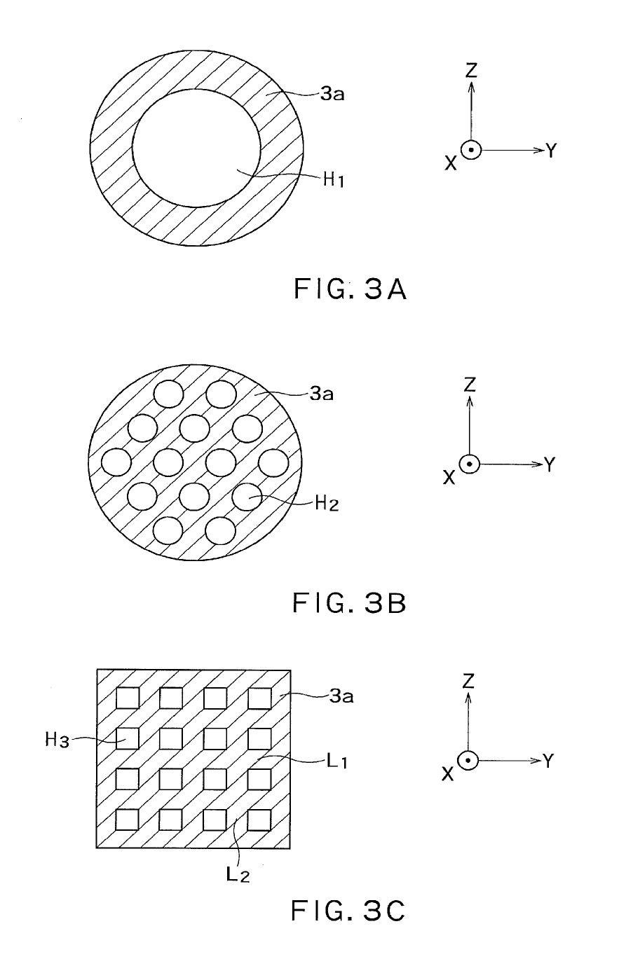

FIGS. 3A to 3C are sectional views illustrating examples of the first metal member 3a of the first embodiment. While these examples illustrate various shapes of the first metal member 3a, these shapes are also applicable to the second metal member 3b.

The metal member 3a in FIG. 3A has a cylindrical shape extending in the X direction, similarly to the metal member 3a in FIG. 1. The FIG. 3A illustrates a YZ cross section of the metal member 3a. The metal member 3a in FIG. 3A has one hole H₁ extending in the X direction. The etching gas introduced into the first vaporizer 15a passes through the outer side of the metal member 3a and the inner side of the hole H₁, and etches the metal member 3a on an outer surface of the metal member 3a and an inner surface of the hole H₁. Therefore, compared to a case where the hole H₁ is not provided, the first metal-containing gas can be generated to contain the metal in a higher concentration. A cross sectional shape of the hole H₁ may be other than a circle.

The metal member 3a in FIG. 3B has plural holes H₂ extending in the X direction. In general, these holes H₂ can further increase the contact area of the metal member 3a and the first etching gas, compared to the hole H₁.

The metal member 3a in FIG. 3C has a mesh-like shape. Specifically, the metal member 3a in FIG. 3C is configured by plural metal wires L₁ extending in the Y direction and plural metal wires L₂ extending in the Z direction, and has plural holes H₃ between these metal wires L₁ and L₂. Therefore, similarly to the above-described two examples, the contact area of the metal member 3a and the first etching gas can be increased.

The first and second metal members 3a and 3b may have shapes different from these examples.

As described above, the semiconductor manufacturing system of the present embodiment includes the vaporizer 15a (and the vaporizer 15b) outside the chamber 11. The vaporizer 15a introduces the etching gas from the gas supply module 14a, and discharges the metal-containing gas that contains the metal etched from the metal member 3a. The chamber 11 introduces the metal-containing gas discharged from the vaporizer 15a, and forms the metal film 2 on the substrate 1 by the metal-containing gas.

Therefore, according to the present embodiment, when a new metal film 2 is to be formed on the substrate 1, various metal films 2 can be easily formed on the substrate 1 by changing the metal member 3a in the vaporizer 15a. According to the present embodiment, when the new metal film 2 is to be formed on the substrate 1, the new metal film 2 can be formed without newly preparing means to house the material of the new metal film 2 and newly preparing means to supply the source gas of the new metal film 2 to the chamber 11.

Also, since the vaporizer 15a of the present embodiment is provided outside the chamber 11, the present embodiment makes it possible to omit the troublesome operation of the chamber 11 when forming the new metal film 2.

Therefore, the present embodiment makes it possible to reduce the time and costs in forming the new metal film 2 on the substrate 1.

While the semiconductor manufacturing system of the present embodiment includes two sets of the gas supply modules 14a and 14b, the vaporizers 15a and 15b, the heaters 16a and 16b and the exhaust valves 17a and 17b, it may include three or more sets of these. This makes it possible to supply three or more kinds of metal-containing gases into the chamber 11. On the other hand, the semiconductor manufacturing system of the present embodiment may include only one set of these.

Also, in a case where the first and second gas supply modules 14a and 14b supply the same etching gas, the first and second gas supply modules 14a and 14b may be integrated into one gas supply module. That is, the same etching gas may be supplied from one gas supply module to the two vaporizers 15a and 15b. This is similar also in the case that the semiconductor manufacturing system of the present embodiment includes three or more sets of gas supply modules and the like.

### Second Embodiment

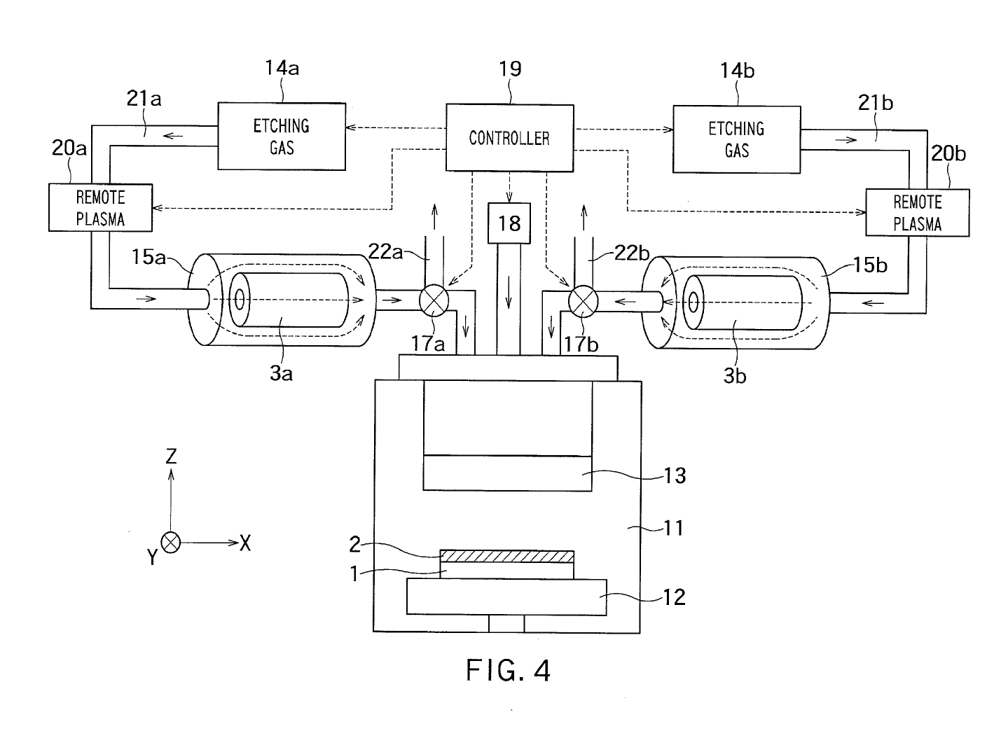

FIG. 4 is a schematic diagram illustrating a configuration of a semiconductor manufacturing system of a second embodiment.

The semiconductor manufacturing system in FIG. 4 includes first and second remote plasma devices 20a and 20b instead of the first and second heaters 16a and 16b. The first and second remote plasma devices 20a and 20b are examples of a plasma generator.

The first remote plasma device 20a is provided on the flow path 21a between the first gas supply module 14a and the first vaporizer 15a, and changes the first etching gas to be introduced to the first vaporizer 15a into plasma. For example, when the first etching gas is the Cl₂ gas, Cl plasma is generated from Cl₂ molecules in the Cl₂ gas, and the Cl plasma is introduced to the first vaporizer 15a. As a result, compared to the case where the first etching gas is not changed into the plasma, the etching of the first metal member 3a is accelerated.

The second remote plasma device 20b is provided on the flow path 21b between the second gas supply module 14b and the second vaporizer 15b, and changes the second etching gas to be introduced to the second vaporizer 15b into the plasma. As a result, compared to the case where the second etching gas is not changed into the plasma, the etching of the second metal member 3b is accelerated.

The controller 19 of the present embodiment control ON/OFF and a voltage between plasma generating electrodes of the first and second remote plasma devices 20a and 20b.

Similarly to the first embodiment, the present embodiment makes it possible to reduce the time and costs for forming the new metal film 2 on the substrate 1. Also, the present embodiment makes it possible, by using the remote plasma devices 20a and 20b instead of the heaters 16a and 16b, to accelerate the etching of the metal members 3a and 3b similarly to the first embodiment.

As a modification of the first and second embodiments, the semiconductor manufacturing system may be provided to include both of the heaters 16a and 16b and the remote plasma devices 20a and 20b.

### Third Embodiment

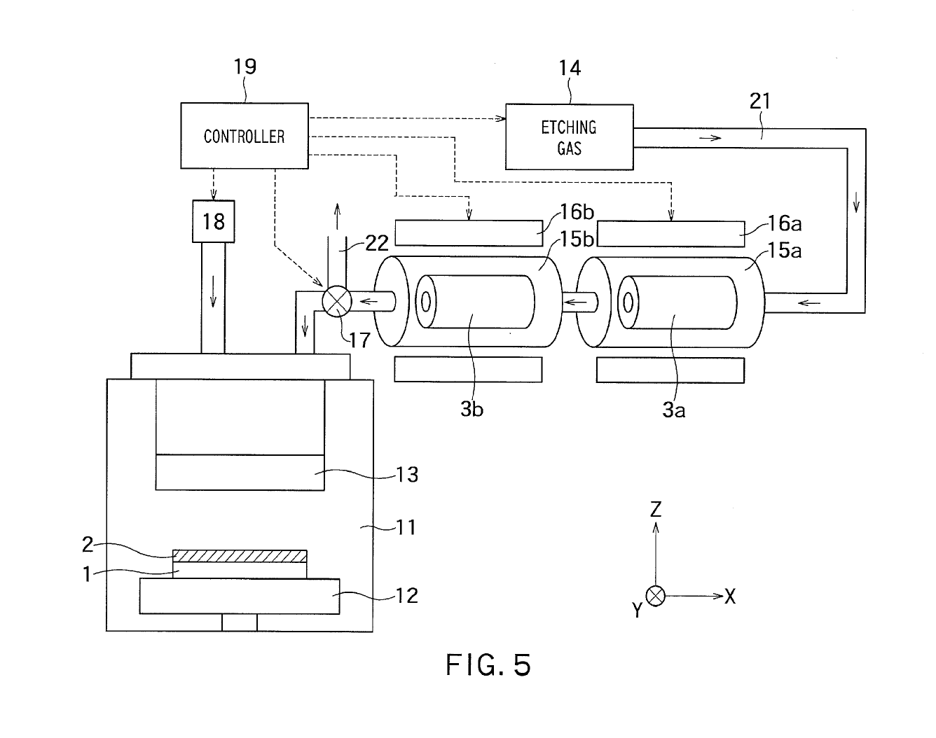

FIG. 5 is a schematic diagram illustrating a configuration of a semiconductor manufacturing system of a third embodiment.

In the semiconductor manufacturing system in FIG. 5, the first and second gas supply modules 14a and 14b are integrated into one gas supply module 14. The configuration of the gas supply module 14 is similar to those of the first and second gas supply modules 14a and 14b. Also, the first vaporizer 15a, the second vaporizer 15b and an exhaust valve 17 are provided in series on a flow path 21 between the gas supply module 14 and the chamber 11. The first and second heaters 16a and 16b are attached to the first and second vaporizers 15a and 15b. The configuration of the exhaust valve 17 is similar to those of the first and second exhaust valves 17a and 17b. The exhaust valve 17 is provided at a contact point of the flow path 21 and a flow path 22.

When the etching gas from the gas supply module 14 is introduced into the first vaporizer 15a, the first metal member 3a is etched by the etching gas. As a result, the first vaporizer 15a discharges the first metal-containing gas that contains the metal etched from the first metal member 3a.

The first metal-containing gas is introduced into the second vaporizer 15b together with the remaining gas of the etching gas. The second metal member 3b is etched by the remaining gas. As a result, the second vaporizer 15b discharges a mixed gas including the first metal-containing gas that contains the metal etched from the first metal member 3a and the second metal-containing gas that contains the metal etched from the second metal member 3b.

When the mixed gas is introduced into the chamber 11, the metal film 2 is formed on the substrate 1 by the metal element in the first metal-containing gas and the metal element in the second metal-containing gas. In this case, in order to reduce these metal-containing gases, the reducing gas is also introduced from the reducing gas supply module 18 into the chamber 11. In the case where it is not needed to cause the reducing reaction in forming the metal film 2 on the substrate 1, the reducing gas may not be introduced from the reducing gas supply module 18 into the chamber 11.

Similarly to the first and second embodiments, the present embodiment makes it possible to reduce the time and costs for forming the new metal film 2 on the substrate 1. Also, the present embodiment makes it possible, by integrating the first and second gas supply modules 14a and 14b into one gas supply module 14, to reduce costs related to the supply of the etching gas.

### Fourth Embodiment

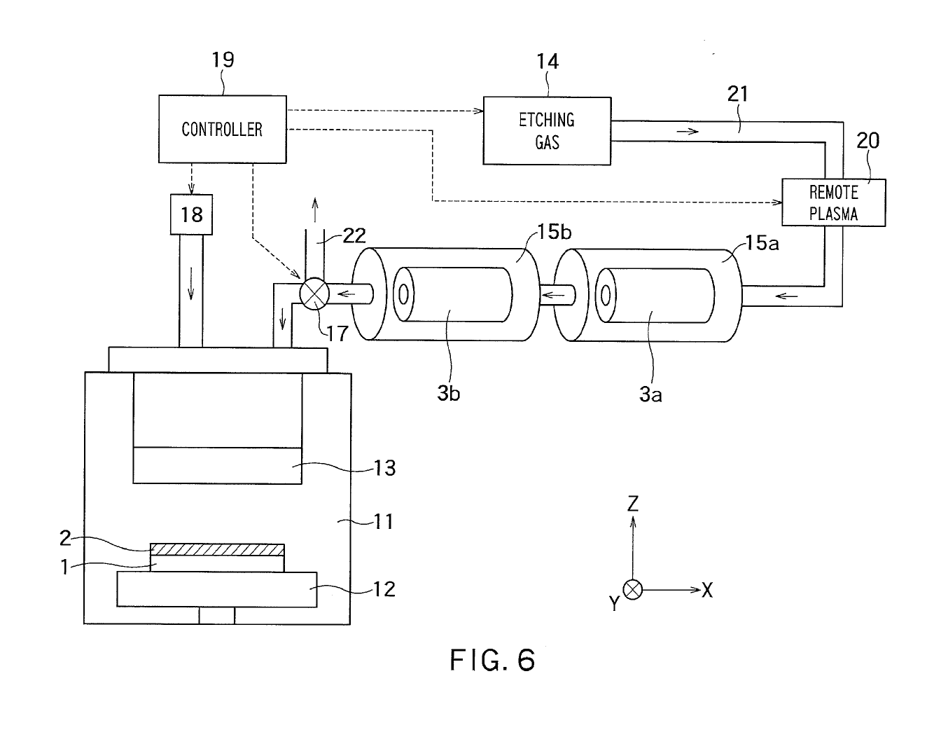

FIG. 6 is a schematic diagram illustrating a configuration of a semiconductor manufacturing system of a fourth embodiment.

The semiconductor manufacturing system in FIG. 6 includes a remote plasma device 20 instead of the heater 16. The configuration of the remote plasma device 20 is similar to those of the first and second remote plasma devices 20a and 20b. In the present embodiment, the etching gas is changed into the plasma and introduced into the first and second vaporizers 15a and 15b.

Similarly to the first to third embodiments, the present embodiment makes it possible to reduce the time and costs for forming the new metal film 2 on the substrate 1. Also, the present embodiment makes it possible, by using the remote plasma device 20 instead of the heater 16, to accelerate the etching of the metal members 3a and 3b similarly to the third embodiment.

As a modification of the third and fourth embodiments, the semiconductor manufacturing system may be provided to include both of the heater 16 and the remote plasma device 20.

While certain embodiments have been described, these embodiments have been presented by way of example only, and are not intended to limit the scope of the inventions. Indeed, the novel systems and methods described herein may be embodied in a variety of other forms; furthermore, various omissions, substitutions and changes in the form of the systems and methods described herein may be made without departing from the spirit of the inventions. The accompanying claims and their equivalents are intended to cover such forms or modifications as would fall within the scope and spirit of the inventions.

1. A semiconductor manufacturing system comprising:
a gas supply module configured to supply an etching gas;
a chamber configured to house a substrate; and
a metal member housing provided outside the chamber and configured to house a metal member, the metal member housing being configured to introduce the etching gas and to discharge a metal-containing gas that contains a metal etched from the metal member by the etching gas,
wherein the chamber is configured to introduce the metal-containing gas discharged from the metal member housing and to form a metal film on the substrate by the metal-containing gas.

2. The system of claim 1, further comprising a heating module configured to heat the metal member in the metal member housing.

3. The system of claim 1, further comprising a plasma generator configured to change the etching gas to be introduced to the metal member housing into plasma.

4. The system of claim 1, further comprising a valve provided between the metal member housing and the chamber and configured to control supply of the metal-containing gas from the metal member housing to the chamber.

5. The system of claim 1, wherein the metal member includes a hole through which the etching gas passes.

6. The system of claim 1, wherein the metal member contains a group 4, 5 or 6 metal element.

7. The system of claim 1, wherein the metal member contains two or more kinds of metal elements.

8. The system of claim 1, wherein the metal film contains a metal element that configures the metal member.

9. The system of claim 1, wherein the etching gas contains a halogen.

10. The system of claim 1, further comprising a reducing gas supply module configured to supply, to the chamber, a reducing gas that reduces the metal-containing gas.

11. The system of claim 10, wherein the reducing gas contains ammonia, monosilane or disilane.

12. The system of claim 1, comprising, as the metal member housing, a first metal housing configured to house a first metal member and a second metal member housing configured to house a second metal member.

13. A semiconductor manufacturing method comprising:
housing a substrate in a chamber;
housing a metal member in a metal member housing provided outside the chamber;
introducing an etching gas into the metal member housing and discharging, from the metal member housing, a metal-containing gas that contains a metal etched from the metal member by the etching gas; and
introducing the metal-containing gas discharged from the metal member housing into the chamber, and forming a metal film on the substrate by the metal-containing gas.

14. The method of claim 13, wherein the metal member includes a hole through which the etching gas passes.

15. The method of claim 13, wherein the metal member contains a group 4, 5 or 6 metal element.

16. The method of claim 13, wherein the metal member contains two or more kinds of metal elements.

17. The method of claim 13, wherein the metal film contains a metal element that configures the metal member.

18. The method of claim 13, wherein the etching gas contains a halogen.

19. The method of claim 13, further comprising supplying, to the chamber, a reducing gas that reduces the metal-containing gas.

20. The method of claim 19, wherein the reducing gas contains ammonia, monosilane or disilane.
